(19) United States
(12) Patent Application Publication
(10) Pub. No.: US 2009/0130841 A1
(43) Pub. Date: May 21, 2009

(54) METHOD FOR FORMING CONTACT IN SEMICONDUCTOR DEVICE

(75) Inventors: Yong-Tae CHO, Ichon-shi (KR); Jae-Kyun LEE, Ichon-shi (KR); Sang- Rok OH, Ichon-shi (KR)

Correspondence Address: TOWNSEND AND TOWNSEND AND CREW, LLP, TWO EMBARCADERO CENTER, EIGHTH FLOOR, SAN FRANCISCO, CA, 94111-3834, US

(73) Assignee: Hynix Semiconductor Inc., Ichon-shi (KR)

(21) Appl. No.: 12/163,434

(22) Filed: Jun. 27, 2008

(30) Foreign Application Priority Data
Nov. 15, 2007 (KR) 10-2007-0116549

(51) Int. Cl. H01L 21/4763

(52) U.S. Cl. 438/637; 257/E21.495

(57) ABSTRACT

A method for forming a contact in a semiconductor device, comprises providing a substrate, forming a plurality of conductive patterns and a passivation layer surrounding the conductive patterns over the substrate, forming an insulation layer covering the conductive patterns and passivation layer, forming a mask pattern for a contact over the insulation layer, forming a first opening by performing an isotropic etch process on the insulation layer using the mask pattern as an etch mask, wherein the isotropic etch process is performed until the insulation layer meets the passivation layer, forming a barrier layer over a resultant structure of the first opening, exposing the insulation layer by performing an anisotropic etch process using the mask pattern as an etch mask, and forming a second opening exposing the substrate by performing a self aligned contact (SAC) process using the mask pattern and barrier layer as an etch mask.

### CROSS-REFERENCE TO RELATED APPLICATIONS

The present invention claims priority of Korean patent application number 2007-0116549, filed on Nov. 15, 2007, which is incorporated by reference in its entirety.

### BACKGROUND OF THE INVENTION

The present invention relates to a method for fabricating a semiconductor device and, more particularly, to a method for forming a contact in a semiconductor device through a self-aligned contact (SAC) process.

As semiconductor devices require higher integration, elements are formed in a stacked structure. Thus, a concept of a contact is introduced. To form the contact, an etch process should be performed on a surface between two structures having a high aspect ratio. Thus, the SAC process is performed to secure an etch profile by using an etch ratio of two materials respectively for the above two structures.

FIGS. 1A to 1E are cross-sectional views describing typical a method for forming a contact through a SAC process.

Referring to FIG. 1A, a conductive pattern 11 is formed over a substrate 10. A plurality of elements such as an isolation layer and a well is formed over the substrate 10. Then, first hard mask 12 is formed over the conductive layer. Spacers 13 are formed on sidewalls of a stack structure of the conductive pattern 11 and hard mask 12. The hard mask 12 and spacers 13 protect the conductive pattern 11 during a subsequent SAC process. Generally, the hard mask 12 and spacers 13 include a nitride layer.

An insulation layer 14 is formed to cover the conductive pattern 11. Generally, the insulation layer 14 includes an oxide layer.

A hard mask layer 15 is formed over the insulation layer 14. The hard mask layer 15 functions as an etch mask during the subsequent SAC process. A photoresist pattern 16 is formed over the second hard mask layer 15 to expose a region to be a contact.

Referring to FIG. 1B, the hard mask layer 15 is etched using the photoresist pattern 16 as an etch mask. Thus, a hard mask pattern 15A is formed to expose a subsequent contact region.

Referring to FIG. 1C, the insulation layer 14 is etched through the SAC process using the hard mask pattern 15A as an etch mask. Part of the substrate 10 is also etched. Thus, an opening 17 is formed to expose the substrate 10. The etched substrate 10 is called a substrate pattern 10A and the etched insulation layer 14 is called an insulation pattern 14A.

Referring to FIG. 1D, a conductive layer 18 for a contact is formed over a resultant structure to fill the opening 17.

Referring to FIG. 1E, a planarization process is performed on the conductive layer 18 until the insulation pattern 14A is exposed to form a contact 18A.

However, the method for forming the typical contact has the following problems.

As semiconductor devices become highly integrated, patterns become ultra-micronized. Accordingly, an overlay between the photoresist pattern 16 and conductive pattern 11 becomes misaligned. In this case, the hard mask 12 and/or spacers 13 may be damaged.

FIG. 2 is a cross-sectional view showing problems of the typical method.

Referring to FIG. 2, an electric short can occur between the conductive pattern 11 and contact 18A (refer to “A”).

When the overlay is misaligned, the contact area between contact 18A and substrate pattern 10A decreases. As a result, a contact resistance increases (refer to “B”).

### SUMMARY OF THE INVENTION

Embodiments of the present invention relate to a method for forming a contact in a semiconductor device using a SAC process.

In this invention, an upper width of an opening for a contact increases to decrease a contact resistance and a barrier layer is formed on sidewalls of the opening with the increased width. Thus, a damage of an insulation layer protecting a conductive pattern can be minimized during a SAC etch process, thereby preventing an electric short between the conductive pattern and contact

In accordance with an aspect of the present invention, there is provided a method for forming a contact in a semiconductor device. The method comprises providing a substrate, forming a plurality of conductive patterns and a passivation layer surrounding the conductive patterns over the substrate, forming an insulation layer covering the conductive patterns and passivation layer, forming a mask pattern for a contact over the insulation layer, forming a first opening by performing an isotropic etch process on the insulation layer using the mask pattern as an etch mask not to reveal the passivation layer, forming a barrier layer over a resultant structure of the first opening, exposing the insulation layer by performing an anisotropic etch process using the mask pattern as an etch mask, and forming a second opening exposing the substrate by performing a self aligned contact (SAC) process using the mask pattern and barrier layer as an etch mask.

### BRIEF DESCRIPTION OF THE DRAWINGS

FIGS. 1A to 1E are cross-sectional views describing typical a method for forming a contact through a SAC process.

FIG. 2 is a cross-sectional view showing problems of the typical method.

FIGS. 3A to 3D are cross-sectional views illustrating a method for forming a contact in a semiconductor device in accordance with an embodiment of the present invention.

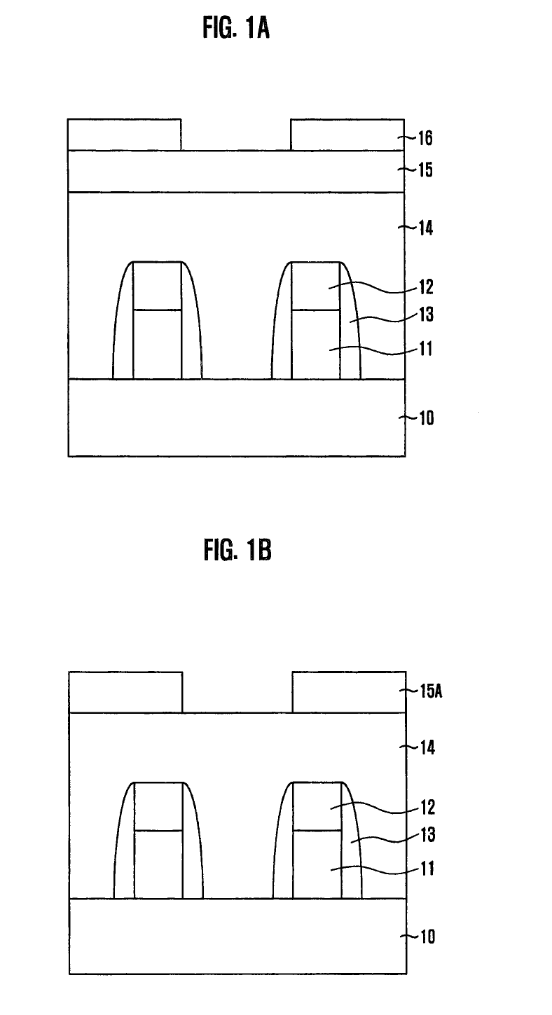

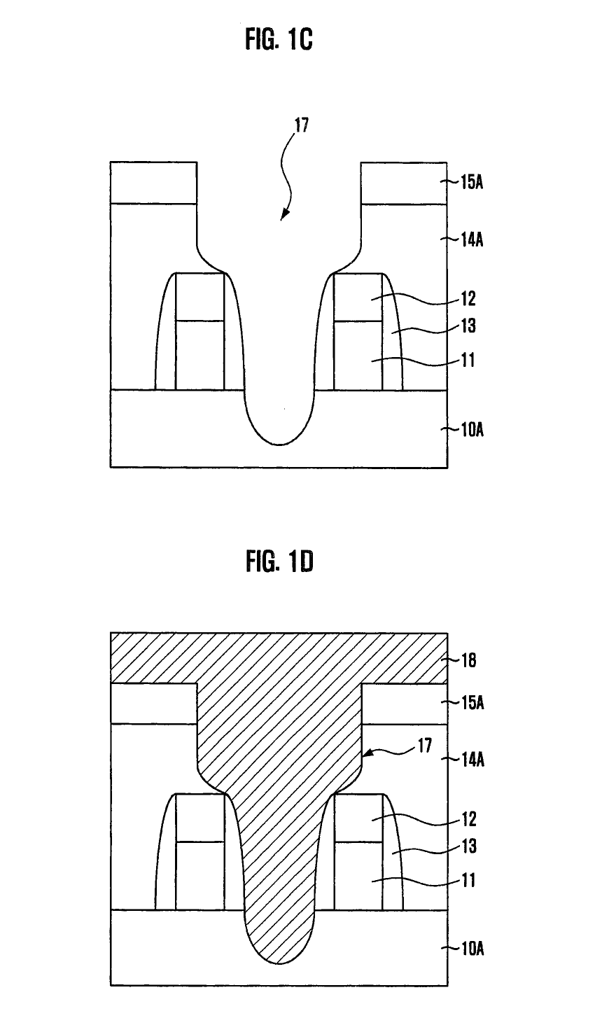

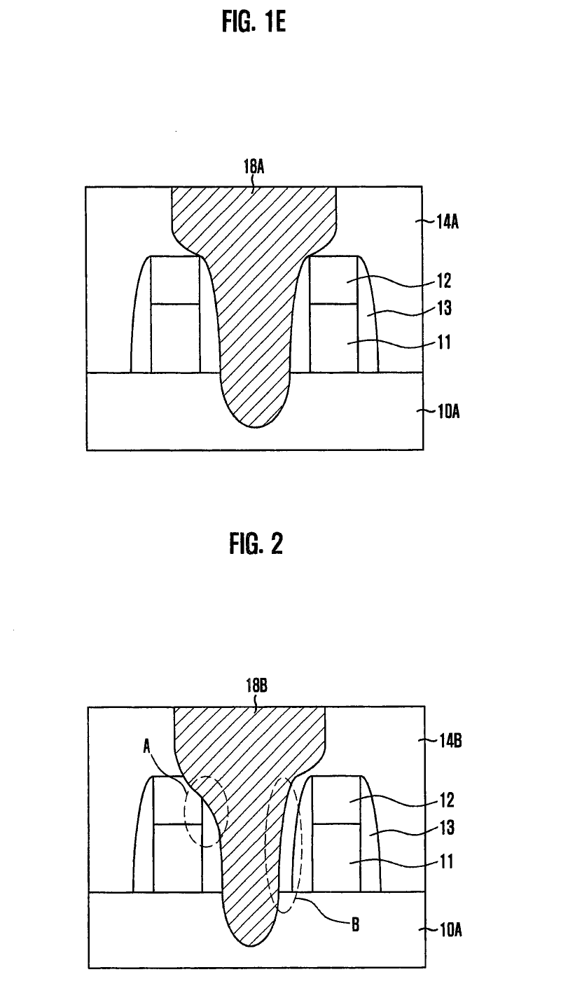

### DESCRIPTION OF SPECIFIC EMBODIMENTS

Embodiments of the present invention relate to a method for a method for forming a contact in a semiconductor device through a SAC process.

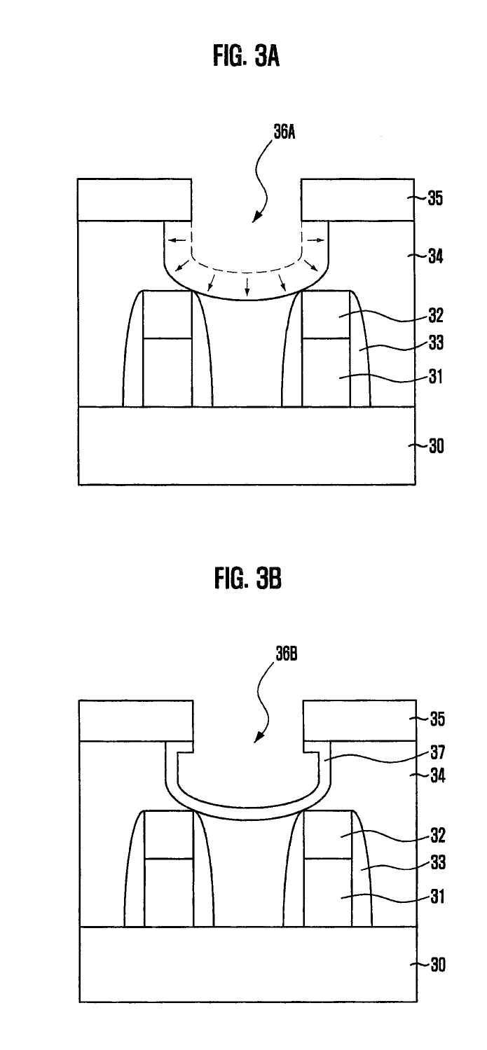

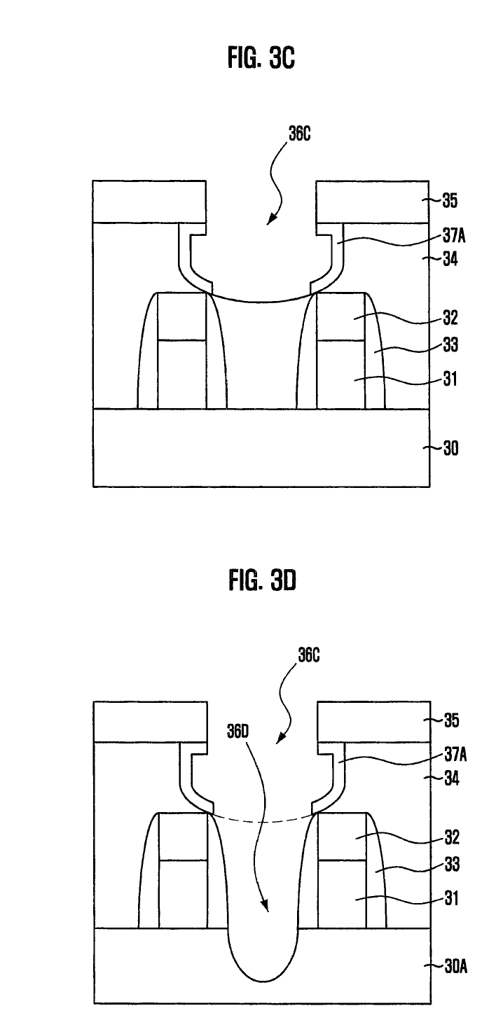

FIGS. 3A to 3D are cross-sectional views illustrating a method for forming a contact in a semiconductor device in accordance with an embodiment of the present invention.

In FIG. 3A, a conductive pattern 31 is formed over a substrate 30. A hard mask 32 is formed over the conductive pattern 31. A structure with a plurality of elements such as an isolation layer and a well is formed over the substrate 30. Spacers 33 are formed on sidewalls of a stack structure of the conductive pattern 31 and the hard mask 32. The hard mask 32 and the spacers 33 protect the conductive pattern 31 during a subsequent SAC process. Generally, the hard mask 32 and spacers 33 include a nitride layer.

An insulation layer 34 is formed to cover the conductive pattern 31. The insulation layer 34 is a layer that can secure a high etch selectivity ratio with the hard mask 32 and spacers 33. The insulation layer 34 may include an oxide layer.

A hard mask layer is formed over the insulation layer 34. The hard mask layer functions as an etch mask during the subsequent SAC process. This hard mask layer is patterned using a photoresist pattern (not shown) forming a hard mask pattern 35.

The insulation layer 34 is anisotropically etched using the hard mask pattern 35 as an etch mask. The anisotropic etch process is stopped before reaching the hard mask 32 (refer to dotted line). This isotropic etch process is performed in a magnetically enhanced reactive ion etching (MERIE) type plasma source applying CₓF_{y} gas (x and y being positive integers) and oxygen (O₂) gas. The CₓF_{y} gas may be one selected from a group consisting of perfluoroethane (C₂F₆), tetrafluoromethane (CF₄), octafluorocyclobutane (C₄F₈), Hexafluoro-1,3-Butadiene (C₄F₆), perfluoropropane (C₃F₈), and hexafluorobenzene (C₆F₆). A ratio of CₓF_{y} to O₂ is approximately 40:1 to approximately 100:1.

In addition, the insulation layer 34 is isotropically etched in a batch-type or a single-type wet etch apparatus using a wet chemical such as hydrofluoric acid (HF) or buffered oxide etch (BOE). Thus, the space etched is wider than the opening of the hard mask pattern 35. The isotropic etch process is performed until a surface of the hard mask 32 is revealed. The hole formed in the insulation layer 34 by the anisotropic etch process is called a first opening 36A. The expansion of this hole by the isotropic etch process forms a cavity called a second opening 36B and is formed to have a greater width than the opening of the hard mask pattern 35.

Referring to FIG. 3B, a barrier layer 37 is formed on a surface of the second opening 36B to prevent damage to the hard mask 32 and/or spacers 33 during the subsequent SAC process. The barrier layer 37 may include a polysilicon layer and have a thickness of approximately 30 Å to approximately 100 Å.

Referring to FIG. 3C, the barrier layer 37 is anisotropically etched using the hard mask pattern 35 as an etch mask and then removed. The anisotropically etched barrier layer 37 is called a barrier pattern 37A. Thus, a third opening 36C is formed. This anisotropic etch process is performed in an inductively coupled plasma (ICP) or a transformer coupled plasma (TCP)-type plasma source applying a gas-mixture of chlorine (Cl₂) and hydrogen bromide (HBr). An etch ratio of the polysilicon for the barrier layer 37 to the material for the hard mask 32 and spacers 33, e.g., the nitride layer, is more than approximately 30:1. Thus, when the barrier layer 37 is etched, the hard mask 32 and/or spacers 33 is rarely damaged.

Referring to FIG. 3D, the SAC process is performed on the exposed insulation layer 34 using the hard mask pattern 35 and barrier pattern 37A as an etch mask. Thus, a fourth opening 36D is formed to extend the third opening 36C and expose the substrate 30. The SAC process is performed in the MERIE-type plasma source applying a gas-mixture of CₓF_{y}/CₗHₘFₙ/O₂ (x,y, l, m, and n being positive integers). The CₓF_{y} gas may be one selected from a group consisting of C₂F₆, CF₄, octafluorocyclobutane (C₄F₈), C₃F₈, and C₆F₆. The CₗHₘFₙ gas may be one of fluoroform (CHF₃) and difluoromethane (CH₂F₂). Since the spacers are protected during the SAC process, damage is minimized. Since the fourth opening 36D is widened, the width of the fourth opening 36D does not greatly decrease even though the overlay is misaligned to a certain degree.

Although not shown, a conductive layer for a contact is formed over a resultant structure including the first opening 36A and fourth opening 36D to sufficiently cover the first opening 36A and fourth opening 36D. Then, a planarization process is performed until the insulation layer 34 is exposed. As a result, a contact simultaneously filled in the first opening 36A and fourth opening 36D is formed.

As described above, when the contact is formed, the first opening 36A with widened width is formed in the insulation layer. Thus, when the overlay is misaligned to a certain degree, a width decrease in the first opening 36A can be minimized. Also, the first opening 36A has a wider width compared to that of the typical method.

Furthermore, when the width of the first opening 36A increases, the etch process is performed until a surface of the insulation layer 34 meets the hard mask 32. Thus, the damage of the hard mask 32 and/or spacers 33 can be minimized during the SAC process.

In this invention, an upper width of an opening for a contact increases to decrease a contact resistance and a barrier layer is formed on sidewalls of the opening with the increased width. Thus, a damage of an insulation layer protecting a conductive pattern can be minimized during a SAC etch process, thereby preventing an electric short between the conductive pattern and contact.

While the present invention has been described with respect to the specific embodiments, the above embodiments of the present invention are illustrative and not limitative. It will be apparent to those skilled in the art that various changes and modifications may be made without departing from the spirit and scope of the invention as defined in the following claims.

What is claimed is:

1. A method for forming a contact in a semiconductor device, the method comprising:
providing a substrate;
forming a plurality of conductive patterns and a passivation layer surrounding the conductive patterns over the substrate;
forming an insulation layer covering the conductive patterns and passivation layer;
forming a mask pattern for a contact over the insulation layer;
forming a first opening by performing an isotropic etch process on the insulation layer using the mask pattern as an etch mask until a surface of the passivation layer is exposed;
forming a barrier layer over a resultant structure with the first opening;
exposing the insulation layer by performing an anisotropic etch process using the mask pattern as an etch mask; and
forming a second opening exposing the substrate by performing a self-aligned contact (SAC) process using the mask pattern and barrier layer as an etch mask.

2. The method of claim 1, wherein the passivation layer includes a nitride layer and the insulation layer includes an oxide layer.

3. The method of claim 1, wherein the isotropic etch process is performed using a wet chemical.

4. The method of claim 1, wherein the barrier layer includes polysilicon.

5. The method of claim 4, wherein the barrier layer is formed to have a thickness of approximately 30 Å to approximately 100 Å.

6. The method of claim 4, wherein the anisotropic process is performed in an inductively coupled plasma (ICP) or a transformer coupled plasma (TCP)-type plasma source applying a gas-mixture of chlorine (Cl₂) and hydrogen bromide (HBr).

7. The method of claim 2, wherein the SAC process is performed in a magnetically enhanced reactive ion etching (MERIE) type plasma source applying a gas-mixture of CₓF_{y} and oxygen (O₂).

8. The method of claim 1, further comprising:
performing an anisotropic etch process on the insulation layer using the mask pattern as an etch mask not to expose the passivation layer, before performing the isotropic etch process on the insulation layer.

9. The method of claim 8, wherein the passivation includes a nitride layer, the insulation layer includes an oxide layer, and the anisotropic etch process is performed in the MERIE plasma source applying a gas-mixture of CₓF_{y} and O₂.

10. The method of claim 9, wherein a ratio of the CₓF_{y} to the O₂ is approximately 40:1 to approximately 100:1.

11. The method of claim 1, further comprising:
forming a conductive layer filling the first and second openings, after forming the second opening.
